(19) United States
(12) Patent Application Publication
(10) Pub. No.: US 2026/0022667 A1
(43) Pub. Date: Jan. 22, 2026

(54) Quick Response Control Design Method for Aero-Engine Starting Process

(71) Applicant: DALIAN UNIVERSITY OF TECHNOLOGY, Dalian (CN)

(72) Inventors: Xudong ZHAO, Dalian (CN); Weichao ZHANG, Dalian (CN); Ning XU, Dalian (CN); Shuoshuo LIU, Dalian (CN); Yan SHI, Dalian (CN)

(21) Appl. No.: 18/848,820

(22) PCT Filed: Jan. 3, 2024
(86) PCT No.: PCT/CN2024/070321

§ 371 Date: Mar. 20, 2025

(30) Foreign Application Priority Data
Jan. 10, 2023 (CN) 202310036782.3

(51) Int. Cl. F02C 7/26; B64D 31/00; F02C 9/26; G06F 30/15

(52) U.S. Cl. CPC F02C 7/26; B64D 31/00; F02C 9/26; G06F 30/15

(57) ABSTRACT

The present invention provides a quick response control design method for an aero-engine starting process and belongs to the field of engine control. With an N-dot control plan, an intelligent optimization algorithm is used to optimize an acceleration target curve, then a controller is designed based on an active disturbance rejection control theory, and finally, the time of the engine starting process is minimized to complete quick response. The present invention can solve the problem that a traditional control method is difficult to ensure time consistency and has low reliability for the transient state of an aero-engine, is a control design method for quick response to the transient state of an aero-engine based on active disturbance rejection control (ADRC) under the N-dot control plan, and can shorten the transient state adjusting time on the premise of achieving stable operation of the aero-engine.

### TECHNICAL FIELD

The present invention belongs to the field of engine control and relates to a control design method for realizing quick response of an aero-engine.

### BACKGROUND

The starting process of an aero-engine is a very complicated transient process, and the aero-engine system in this process has obvious nonlinear and time-varying characteristics. However, the starting performance directly affects the flight safety and application of an aircraft and the reliability and service life of an engine, so it is very important to study the control on the starting process.

It is difficult to ensure time consistency and high reliability by using traditional starting control schemes. For an aero-engine, when a mechanical hydraulic control system is used, an adjuster cannot be designed too complex, and generally, only an open-loop fuel supply adjustment scheme can be selected, so phenomena of starting overtemperature or suspension often occur, and the starting performance is subject to various external factors. An acceleration control method that is commonly used at present is open-loop control based on fuel planning. This method is simple and easy, but the acceleration performance thereof is not consistent for different engines of the same batch or different life stages of the same engine. In this regard, a closed-loop control method based on an N-dot control plan has been proposed in the existing literature. In A Design Method of N-dot Transient State PI Control Laws, Wang Xi et al. verifies through simulation that a closed-loop proportional integral (PI) control strategy using rotor acceleration can ensure that the acceleration performance of the engine is not affected by component degradation, but the traditional PI control strategy has a long response time, and still has some limitations in practical application, which limits the practicability of the model.

A particle swarm optimization (PSO) algorithm, as a bionic evolutionary algorithm, is proposed under the enlightenment of the behavior mechanism of biological populations in nature. The PSO algorithm is an evolutionary computation method proposed by an American social psychologist J. Kennedy and an American electrical engineer R. Eberhart in 1995. The PSO algorithm originates from the study of artificial life, especially the imitation of the behavior mechanism of populations such as birds and fish, draws on the biological population model proposed by a biologist F. Heppner, and also integrates the idea of evolutionary computation. The concept of the PSO algorithm is relatively simple, not many parameters need to be adjusted, the PSO algorithm is easy to program and has no complicated mathematical operations, and the velocity and storage requirements for computer hardware are not high.

As a bionic algorithm, the PSO algorithm has no complete mathematical theoretical basis at present, but as a new optimization algorithm, has shown a good application prospect in many fields. Therefore, it is of great significance to conduct in-depth research on the PSO algorithm in both theory and practice.

The patent of the present invention makes use of the improved PSO algorithm which has the advantages of easy implementation, good effect and good universality, and is used to solve the problem of time optimal starting control under many constraints. Firstly, it is necessary to discretize the designed objective function, namely the starting process time, and obtain an optimal control plan of the whole starting process by ensuring that the starting process time of each sub-time period is optimal. Because intelligent algorithms have better search capability in dealing with performance optimization problems of an aero-engine, the performance parameters of the engine converge faster. However, the intelligent algorithms also have some disadvantages, such as easily running into the local optimization solution and high calculation complexity. Therefore, it is necessary to analyze the applicability of the algorithm according to the specific situation.

### SUMMARY

In view of the problems in the prior art, the present invention provides a control design method for realizing quick response to a transient state of an aero-engine, which can shorten the transient state adjusting time without surging or overtemperature in the starting process of an aero-engine.

To achieve the above purpose, the present invention adopts the following technical solution: A control design method for a control plan of quick response to a transient state of an aero-engine, comprising: firstly, designing an active disturbance rejection controller (ADRC) based on an N-dot control plan; secondly, constructing a competitive particle swarm intelligent control algorithm; and finally, applying the algorithm to a model to obtain an ideal control result. The present invention can shorten the transient state adjusting time on the premise of achieving stable operation of the aero-engine. Specific steps are as follows:

### Step 1: Designing an ADRC Based on an N-Dot Control Plan

The N-dot control plan has the features that closed-loop control under the N-dot control plan can ensure the accelerated consistency of an aero-engine, respond to a transient control plan in a short time, and give full play to the potential of the engine. Starting process control is an important part of transient control of the aero-engine, and it is required to ensure that the engine has no surging or overtemperature during the process and the starting time is shortened. Based on the above research, the present invention adopts an ADRC algorithm instead of a PI control algorithm, and is applied to starting process control of the aero-engine. A closed-loop control circuit is constructed as shown in FIG. 1, and the specific steps are as follows:
(1) The open-loop property of an open-loop fuel-air ratio control plan determines that fuel can only be supplied to the aero-engine in accordance with the originally designed acceleration/deceleration plan, but the transient control cannot be more flexible and detailed according to the real-time state of the aero-engine. In addition, the open-loop fuel-air ratio control plan also has the defects of integral saturation and great influence of component degradation on performance. In this context, the more advantageous N-dot control plan has become one of the main methods for transient control. By controlling the rotor acceleration of the engine, the N-dot control plan ensures that the engine with manufacturing tolerance and performance degradation achieves the goal of consistent transient state performance.
(2) The ADRC mainly comprises the following parts: a tracking differentiator (TD), a linear extended state observer (LESO), and nonlinear state error feedback (NLSEF). The characteristics include: 1) The contradiction between rapidity and overshoots of the control system is solved by arranging a transient process. 2) An extended state observer is used to estimate disturbance of the system in real time and compensate the disturbance to enhance the robustness of the system. 3) A linear state error combination method is adopted to significantly improve the control function. An n-order structural diagram is shown in FIG. 2. A second-order tracking differential equation is as follows:

$$\{ \begin{matrix}{v}_{1} ( k + 1 ) = {v}_{1} ( k ) + h * {v}_{2} ( k ) \\ {v}_{2} ( k + 1 ) = {v}_{2} ( k ) h * fhan ( {v}_{1} - {v}_{0} , {v}_{2} , r , {h}_{0} )\end{matrix}$$

wherein v₀ is a reference set value of high-pressure shaft rotor acceleration N-dot, and v₁ is a tracking value of reference input; v₂ is a tracking value of an N-dot derivative; r is a velocity factor, which is a physical quantity that determines how fast or slow to track; h is a sampling point of the system; h₀ is a filtering factor; and fhan(v₁−v₀,v₂,r,h₀) is a nonlinear function.
(3) The N-dot control plan and the ADRC are combined, which retains the characteristics of the N-dot control plan and introduces the ADRC to enhance strong immunity and strong robustness of closed-loop control. FIG. 3 shows an ADRC closed-loop control structure based on an N-dot control plan designed in an aero-engine starting model.

### Step 2: Constructing a Competitive Particle Swarm Intelligent Control Algorithm

The intelligent control algorithm has the feature that the problem that a traditional optimization algorithm has too many constraints or has multiple extreme values and thus cannot obtain an optimal solution can be solved.
(1) Considering that the traditional particle swarm algorithm has a good effect on small-range particle optimization, but cannot reach the required optimization standard for large-range particle optimization. Inspired by the traditional PSO algorithm, the patent of the present invention utilizes a new competitive particle swarm optimization (CSO) algorithm for large-scale optimization. This algorithm is conceptually very different from the traditional PSO algorithm, which does not involve neither the individual best position of each particle nor the global best position (or the neighborhood best position) when updating particles in a new CSO algorithm. On the contrary, a paired competitive mechanism is introduced, under which losing particles will update positions thereof by learning from winning particles.
(2) Without loss of generality, the present invention considers the following minimization problem:

$$min f = f ( X )$$

$$s . t . X {∈}_{𝒳}$$

wherein χ∈Rⁿ is a set of feasible solutions, and n is the dimension of searching space, i.e., the number of decision variables.

To solve the above optimization problem, a population P(t) containing m particles is randomly initialized and iteratively updated, wherein m is called a population size, and t is a generating index. Each particle has a two-dimensional position, Xᵢ(t)=(x_{i,1}(t), x_{i,2}(t), . . . , x_{i,n}(t)), indicating a candidate solution of the above optimization problem, and an n-dimensional velocity vector, Vᵢ(t)=(v_{i,1}(t), v_{i,2}(t), . . . , v_{i,n}(t)). In each generation, particles in P(t) are randomly assigned to m/2 pairs (the population size m is assumed to an even number) and then compete between two particles in each pair. As a result of each competition, particles with better fitness (hereinafter referred to as winners) will be passed directly to the next generation P(t+1) of the population, while losing particles (losers) will update the positions and velocities thereof by learning from the winners. After learning from the winners, the losers will also be passed to the particle swarm P(t+1), which means that each particle enters the competition only once. In other words, for the population size m, an m/2 competition occurs so that all the m particles compete once, and the positions and velocities of m/2 particles will be updated.

X_{w,k}(t) and X_{l,k}(t) as well as V_{w,k}(t) and V_{l,k}(t) are respectively used to indicate positions and velocities of winners and losers in a k^{th} round of a t^{th} generation, wherein k=1, 2, . . . , m/2. Therefore, the velocity of the losing particles after the k^{th} competition is updated by using the following learning strategy:

$${V}_{l , k} ( t + 1 ) = {R}_{1} ( k , t ) {V}_{l , k} ( t ) + {R}_{2} ( k , t ) ( {X}_{w . k} ( t ) - {X}_{l . k} ( t ) ) + φ {R}_{3} ( k , t ) ( {X}_{k} ( t ) - {X}_{l , k} ( t ) )$$

Meanwhile, the positions of the losers can be updated with new velocities.

$${X}_{l , k} ( t + 1 ) = {X}_{l . k} ( t ) + {V}_{l . k} ( t + 1 )$$

wherein R₁(k,t), R₂(k,t) and R₃(k,t)∈[0,1]ⁿ are three vectors randomly generated after the k^{th} competition and learning process in the t^{th} generation, X̅ₖ(t) is an average position value of correlated particles, and φ is a parameter that controls the effect of X̅ₖ(t).
(3) The convergence of the search behavior of the proposed CSO has been proved by the existing literature, and the development ability hereof has been empirically analyzed. The results show that the proposed CSO has a good balance in the development ability. Although the algorithm is simple, the existing experimental results show that for a set of widely used large-scale optimization problems, the proposed CSO exhibits better overall performance than five state-of-the-art meta-heuristic algorithms, and can effectively solve the problems of up to 5000 dimensions. Based on the advantages, the patent of the present invention selects the CSO algorithm to solve the fuel-air ratio optimization problem in the starting process. The flow of the CSO algorithm is shown in FIG. 5.
   Step 3: Obtaining a Control Result in Combination with the Model
(1) Optimization result of CSO algorithm: parameters are preset in an optimization program, and then different predicted numbers of steps, different numbers of iterations and different numbers of competing particles are set respectively.
   (1.1) The predicted number of steps is set to 1, the number of iterations is set to 60, and the number of competing particles is set to 30. In this case, the preset parameters are optimized, an optimized fuel-air ratio curve is input into a starting model, and finally, an optimized high-pressure shaft speed rising curve can be obtained.
   (1.2) The predicted number of steps is set to 1 and 2, the number of iterations is set to 60, and the number of competing particles is set to 30, which are used for illustrating the effect of the predicted number of steps on the optimization result, and the result shows that the larger the predicted number of steps is, the further the number is from the lower limit, the larger the surging margin is, and the better the optimization effect is.
   (1.3) The predicted number of steps is set to 1, the number of iterations is set to 400, and the number of competing particles is set to 200, which are used for illustrating the effect of the number of iterations and the number of particles on optimization, and the result shows that the increase of the number of iterations and the number of particles will make the optimization result smoother and better.
(2) Optimization result of ADRC based on N-dot control plan: the present invention takes the obtained high-pressure shaft speed curve as a control target value for closed-loop tracking control. As long as the optimized target curve can be tracked better, the limit will not be exceeded, and the time of response to the transient state will be shorter. In a contrast experiment, the ADRC algorithm based on N-dot can control the errors to zero quickly, while the single PID algorithm and the PID algorithm based on N-dot need a period of time to stabilize the errors to zero, and especially at a steady-state point, the change is more drastic, which reflects the superior performance of the ADRC based on the N-dot control plan.

The present invention has the following beneficial effects:

Under the N-dot control plan, the accelerated consistency of the aero-engine can be guaranteed, and the control scheme for the transient state can get response in a short time to give full play to the potential of the engine, which can solve the problem that a traditional optimization algorithm has too many constraints or has multiple extreme values and thus cannot obtain an optimal solution.

On the premise of safe and stable operation of the aero-engine, the present invention can shorten the starting time, so as to quickly reach a specified speed to achieve the thrust requirement of the engine, thus better adapting to the environment of the engine.

### DESCRIPTION OF DRAWINGS

FIG. 1 shows an ADRC closed-loop control circuit based on an N-dot control plan;

FIG. 2 is a structural diagram of an ADRC;

FIG. 3 shows an ADRC closed-loop control structure based on an N-dot control plan;

FIG. 4 is a flow chart of a PSO algorithm;

FIG. 5 is a flow chart of a CSO algorithm;

FIG. 6 shows an internal structure of a controller;

FIG. 7 is a structural schematic diagram of closed-loop logic;

FIG. 8(a) shows comparison of tracking performance of a high-pressure shaft speed curve; and FIG. 8(b) is a local enlarged view of Position A in FIG. 8(a);

FIG. 9 shows comparison of tracking errors.

### DETAILED DESCRIPTION

The present invention is further described below through specific embodiments in combination with drawings.

A control design method for a control plan of quick response to a transient state of an aero-engine, comprising: firstly, designing an ADRC based on an N-dot control plan; secondly, constructing a competitive particle swarm intelligent control algorithm; and finally, applying the algorithm to a model to obtain an ideal control result.

### Step 1: Designing an ADRC Based on an N-Dot Control Plan;

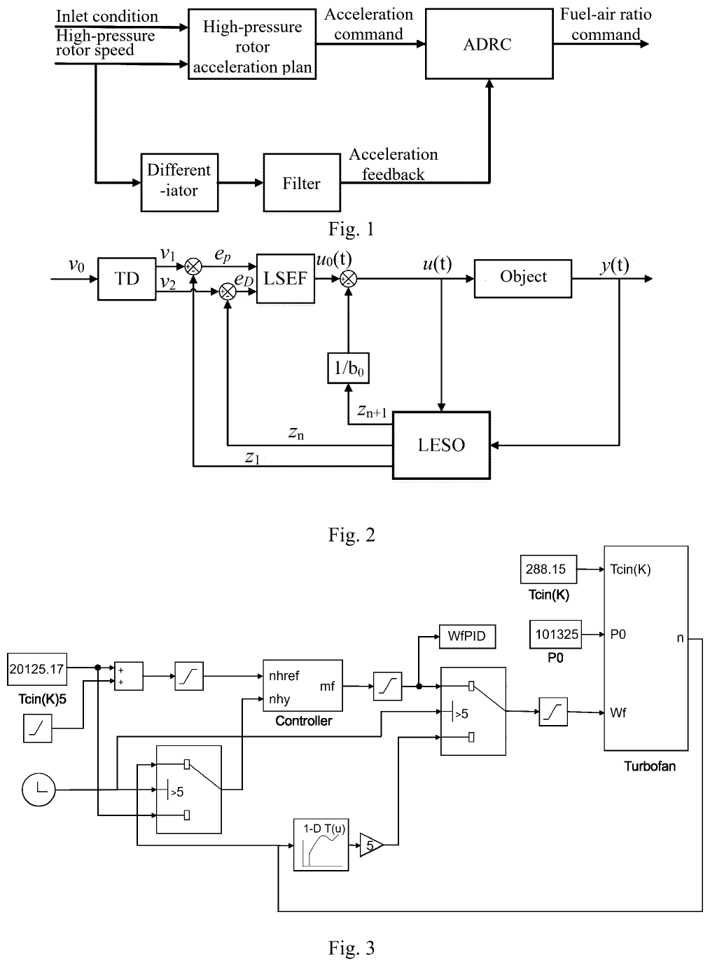

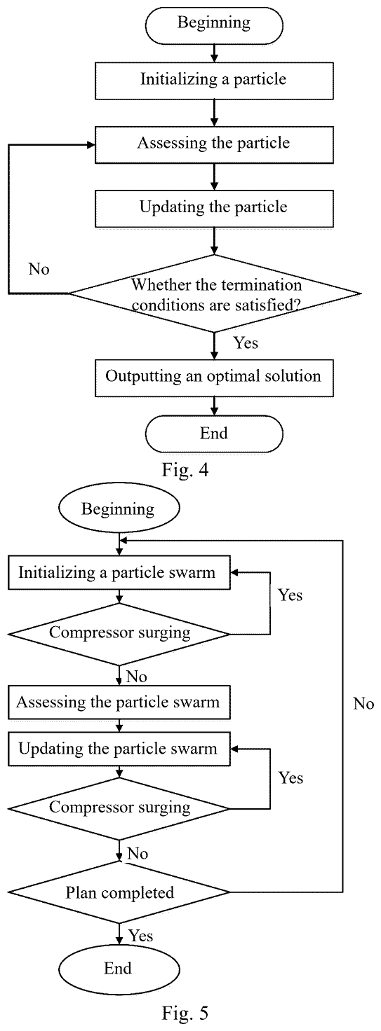

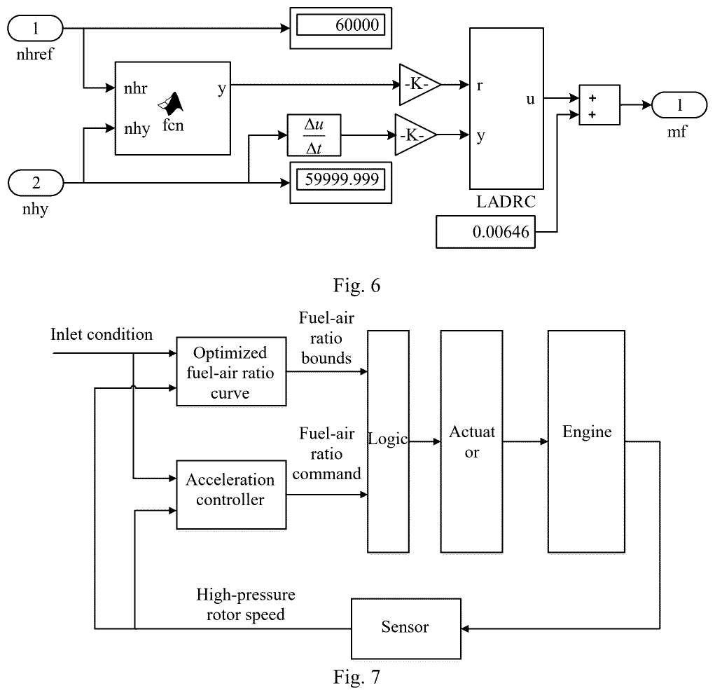

The N-dot control plan has the features that closed-loop control under the N-dot control plan can ensure the accelerated consistency of an aero-engine, respond to a transient control plan in a short time, and give full play to the potential of the engine. Starting process control is an important part of transient control of the aero-engine, and it is required to ensure that the engine has no surging or overtemperature during the process and the starting time is shortened. Based on the above research, the present invention adopts an ADRC algorithm instead of a PI control algorithm, and is applied to starting process control of the aero-engine. A closed-loop control circuit is constructed as shown in FIG. 1, and the specific steps are as follows:
(1) The open-loop property of an open-loop fuel-air ratio control plan determines that fuel can only be supplied to the aero-engine in accordance with the originally designed acceleration/deceleration plan, but the transient control cannot be more flexible and detailed according to the real-time state of the aero-engine. In addition, the open-loop fuel-air ratio control plan also has the defects of integral saturation and great influence of component degradation on performance. In this context, the more advantageous N-dot control plan has become one of the main methods for transient control. By controlling the rotor acceleration of the engine, the N-dot control plan ensures that the engine with manufacturing tolerance and performance degradation achieves the goal of consistent transient state performance.
(2) The ADRC mainly comprises the following parts: a tracking differentiator (TD), a linear extended state observer (LESO), and nonlinear state error feedback (NLSEF). The characteristics include: 1) The contradiction between rapidity and overshoots of the control system is solved by arranging a transient process. 2) An extended state observer is used to estimate disturbance of the system in real time and compensate the disturbance to enhance the robustness of the system. 3) A linear state error combination method is adopted to significantly improve the control function. An n-order structural diagram is shown in FIG. 2. A second-order tracking differential equation is as follows:

$$\{ \begin{matrix}{v}_{1} ( k + 1 ) = {v}_{1} ( k ) + h * {v}_{2} ( k ) \\ {v}_{2} ( k + 1 ) = {v}_{2} ( k ) h * fhan ( {v}_{1} - {v}_{0} , {v}_{2} , r , {h}_{0} )\end{matrix}$$

wherein v₀ is a reference set value of high-pressure shaft rotor acceleration N-dot, and v₁ is a tracking value of reference input; v₂ is a tracking value of an N-dot derivative; r is a velocity factor, which is a physical quantity that determines how fast or slow to track; h is a sampling point of the system; h₀ is a filtering factor; and fhan(v₁−v₀,v₂,r,h₀) is a nonlinear function.
(3) The N-dot control plan and the ADRC are combined, which retains the characteristics of the N-dot control plan and introduces the ADRC to enhance strong immunity and strong robustness of closed-loop control. FIG. 3 shows an ADRC closed-loop control structure based on an N-dot control plan designed in an aero-engine starting model. It can be seen from FIG. 3 that the bottom output line is connected to an interpolation module, Turbofan, which switches at the 5^{th} second to simulate starter motoring. In FIG. 3, the controller is the one to be emphatically introduced in the present invention, in which an ADRC based on an N-dot control plan and a PID controller can be integrated for the subsequent contrast experiment. The internal structure of the controller is shown in FIG. 6. An MATLAB function is inside the controller, which divides the high-pressure rotor speed difference into regions. When the error between an output high-pressure rotor speed and a target value is greater than or less than a certain value, the present invention makes the input of the controller constant, i.e., the high-pressure shaft rotor acceleration is constant (the high-pressure shaft speed rises or falls according to a certain slope), so as to ensure that the input of the controller is not too large and thus exceeds certain limits during engine operation; and when the error is in the middle region, the error is subjected to multiplied processing to make the controller respond quickly. In FIG. 6, the acceleration value of the high-pressure rotor speed is obtained by a differential module, and is subjected to multiplied reduction by an amplifier, wherein k=1/100. Since the rotor acceleration is too sensitive, when the speed has a certain change, the rotor acceleration may be very large. To ensure that the ADRC can be observed in time, the present invention carries out multiplied scaling, which is convenient for control, and the input is also subjected to the same operation. The output of the controller is superimposed with an open-loop fuel-air ratio of 0.00646369 pps. Because the switch from interpolation to closed loop after 5 s requires operation based on a certain fuel-air ratio, the open-loop fuel-air ratio replaces the fuel-air ratio at the last moment before the switch. The deviation between a high-pressure shaft speed command and a feedback value is taken as the input of the controller, and the output is an accelerated fuel-air ratio command. The fuel command is not directly transmitted to the engine, but transmitted to the engine through low-selection logic together with the optimized fuel-air ratio point, so as to realize the acceleration process control. The structural schematic diagram is shown in FIG. 7.

### Step 2: Constructing a Competitive Particle Swarm Intelligent Control Algorithm

The intelligent control algorithm has the feature that the problem that a traditional optimization algorithm has too many constraints or has multiple extreme values and thus cannot obtain an optimal solution can be solved.
(1) Considering that the traditional particle swarm algorithm has a good effect on small-range particle optimization, but cannot reach the required optimization standard for large-range particle optimization. Inspired by the traditional PSO algorithm, the patent of the present invention utilizes a new competitive particle swarm optimization (CSO) algorithm for large-scale optimization. This algorithm is conceptually very different from the traditional PSO algorithm, which does not involve neither the individual best position of each particle nor the global best position (or the neighborhood best position) when updating particles in a new CSO algorithm. On the contrary, a paired competitive mechanism is introduced, under which losing particles will update positions thereof by learning from winning particles.
(2) Without loss of generality, the present invention considers the following minimization problem:

$$min f = f ( X )$$

$$s . t . X {∈}_{𝒳}$$

wherein χ∈Rⁿ is a set of feasible solutions, and n is the dimension of searching space, i.e., the number of decision variables.

To solve the above optimization problem, a population P(t) containing m particles is randomly initialized and iteratively updated, wherein m is called a population size, and t is a generating index. Each particle has a two-dimensional position, Xᵢ(t)=(x_{i,1}(t), x_{i,2}(t), . . . , x_{i,n}(t)), indicating a candidate solution of the above optimization problem, and an n-dimensional velocity vector, Vᵢ(t)=(v_{i,1}(t), v_{i,2}(t), . . . , v_{i,n}(t)). In each generation, particles in P(t) are randomly assigned to m/2 pairs (the population size m is assumed to an even number) and then compete between two particles in each pair. As a result of each competition, particles with better fitness (hereinafter referred to as winners) will be passed directly to the next generation P(t+1) of the population, while losing particles (losers) will update the positions and velocities thereof by learning from the winners. After learning from the winners, the losers will also be passed to the particle swarm P(t+1), which means that each particle enters the competition only once. In other words, for the population size m, an m/2 competition occurs so that all the m particles compete once, and the positions and velocities of m/2 particles will be updated.

X_{w,k}(t) and X_{l,k}(t) as well as V_{w,k}(t) and V_{l,k}(t) are respectively used to indicate positions and velocities of winners and losers in a k^{th} round of a t^{th} generation, wherein k=1, 2, . . . , m/2. Therefore, the velocity of the losing particles after the k^{th} competition is updated by using the following learning strategy:

$${V}_{l , k} ( t + 1 ) = {R}_{1} ( k , t ) {V}_{l , k} ( t ) + {R}_{2} ( k , t ) ( {X}_{w . k} ( t ) - {X}_{l . k} ( t ) ) + φ {R}_{3} ( k , t ) ( {X}_{k} ( t ) - {X}_{l , k} ( t ) )$$

Meanwhile, the positions of the losers can be updated with new velocities.

$${X}_{l , k} ( t + 1 ) = {X}_{l . k} ( t ) + {V}_{l . k} ( t + 1 )$$

wherein R₁(k,t), R₂(k,t) and R₃(k,t)∈[0,1]ⁿ are three vectors randomly generated after the k^{th} competition and learning process in the t^{th} generation, X̅ₖ(t) is an average position value of correlated particles, and φ is a parameter that controls the effect of X̅ₖ(t).

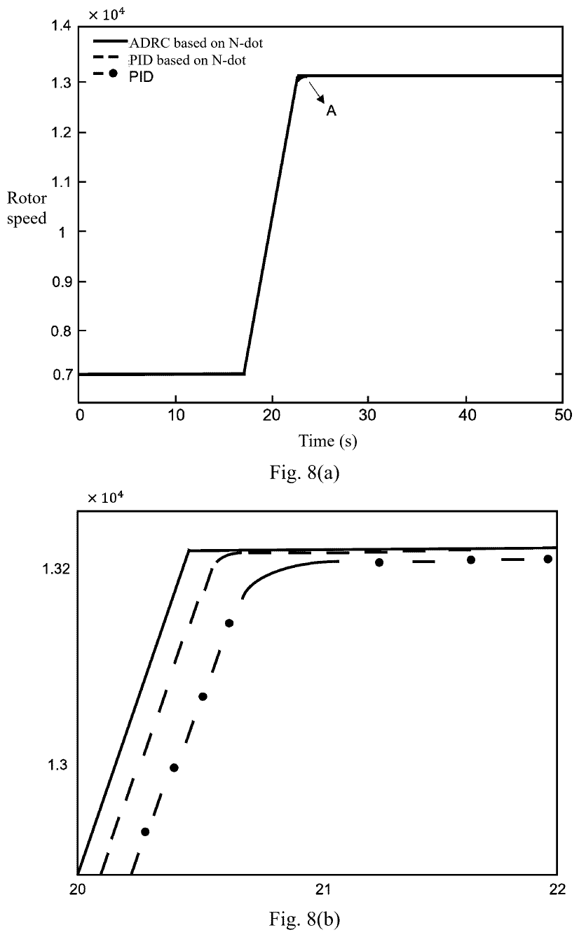

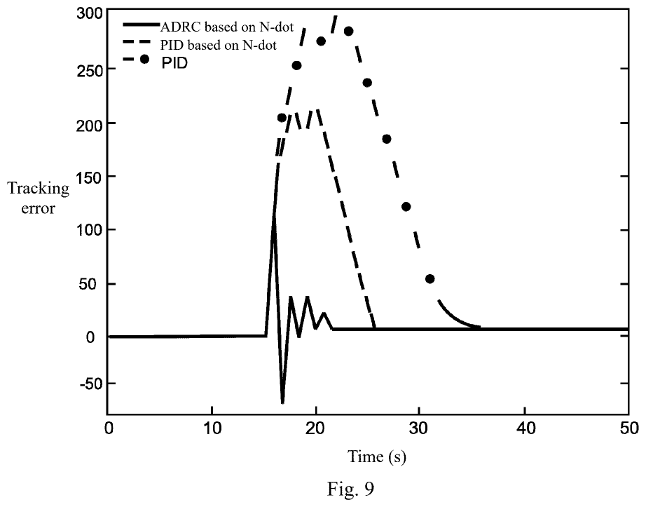

A rotor acceleration plan is the core of an acceleration controller used to prevent compressor surging or turbine inlet overtemperature caused by excessive rotor acceleration during acceleration, and is usually designed as a function of a high-pressure rotor corrected speed. The present invention uses the CSO algorithm to optimize the rotor acceleration plan, which can provide a basis for the design of subsequent control parameters. Considering the acceleration process of the engine: in order to increase the engine speed, the most direct way is to increase the fuel-air ratio at a certain rate, the greater the change rate of fuel is, the faster the speed is increased, the shorter the acceleration process time is, but the engine may surge or overheat. During acceleration, the high-pressure rotor acceleration increases first and then decreases, i.e., the rotor acceleration has a maximum value. Therefore, the design of the rotor acceleration plan can be expressed as follows: providing flight conditions, the process of motoring the engine by the starter before ignition at the first stage is ignored, because considering the role of the starter will make the optimization process too complicated, the process of starter motoring is not considered. Optimization is started from the power generated by the engine. Under the condition of ensuring the minimum high-pressure rotor surging margin limit and the maximum turbine inlet temperature limit, the CSO algorithm is used to make the high-pressure shaft speed reach the target value as quickly as possible. The feedback value of the rotor acceleration cannot be measured directly, and thus is treated by a difference method and smoothed with a filter.
(3) The convergence of the search behavior of the proposed CSO has been proved by the existing literature, and the development ability hereof has been empirically analyzed. The results show that the proposed CSO has a good balance in the development ability. Although the algorithm is simple, the existing experimental results show that for a set of widely used large-scale optimization problems, the proposed CSO exhibits better overall performance than five state-of-the-art meta-heuristic algorithms, and can effectively solve the problems of up to 5000 dimensions. Based on the advantages, the patent of the present invention selects the CSO algorithm to solve the fuel-air ratio optimization problem in the starting process. The flow of the CSO algorithm is shown in FIG. 5.
   Step 3: Obtaining a Result in Combination with the Model
(1) Optimization result of CSO algorithm: parameters are preset in an optimization program, the optimization time is set to 7 s, the sampling time (simulation step) of the system is 0.1 s, the target value of the high-pressure shaft speed is 13230, the temperature limit is defined as 1100, the lower limit of the surging margin is set to 0.3, optimization is started from 17.3 s, the initial fuel-air ratio is set to 0.1036, and the upper and lower bounds of the fuel-air ratio are 1.73 and 0.1010 respectively; and the upper and lower bounds of the variation of the fuel-air ratio are 0.05 and −0.05.
   (1.1) The predicted number of steps is set to 1, the number of iterations is set to 60, and the number of competing particles is set to 30. In this case, the preset parameters are optimized, the obtained fuel-air ratio is neither higher than the upper bound of 1.73 nor lower than the lower bound of 0.1010, satisfying the optimization requirements, an optimized fuel-air ratio curve is input into a starting model, and finally, an optimized high-pressure shaft speed rising curve can be obtained.
   (1.2) The predicted number of steps is set to 1 and 2, the number of iterations is set to 60, and the number of competing particles is set to 30, which are used for illustrating the effect of the predicted number of steps on the optimization result, and the result shows that the larger the predicted number of steps is, the further the number is from the lower limit, the larger the surging margin is, and the better the optimization effect is.
   (1.3) The predicted number of steps is set to 1, the number of iterations is set to 400, and the number of competing particles is set to 200, which are used for illustrating the effect of the number of iterations and the number of particles on optimization, and the result shows that the increase of the number of iterations and the number of particles will make the optimization result smoother and better.
(2) Optimization result of ADRC based on N-dot control plan: the present invention takes the obtained high-pressure shaft speed curve as a control target value for closed-loop tracking control. As long as the optimized target curve can be tracked better, the limit will not be exceeded, and the time of response to the transient state will be shorter. As shown in FIG. 8, the tracking ability of PID is weakest, the tracking ability of ADRC based on N-dot is strongest, and the present invention finds from the enlarged part that ADRC can almost perfectly track the target speed, and the effect of PID based on N-dot is relatively poor but much better than the control effect of a single PID. Finally, the present invention observes the performance of three control algorithms through changes of tracking errors in FIG. 9. The present invention can find that the ADRC algorithm based on N-dot can control the errors to zero quickly, while the single PID and the PID based on N-dot need a period of time to stabilize the errors to zero, and especially in the case of drastic changes at the steady-state point, the contrast effect is more obvious, which highlights the superior performance of the proposed control algorithm.

Matters not covered by the present invention are known technologies.

The above embodiments only aim to explain the technical conception and characteristics of the present invention, and are intended to make those skilled in the art know the content of the present invention and implement same accordingly, which cannot limit the protection scope of the present invention. Any equivalent change or modification made according to the spirit substance of the present invention shall be covered within the protection scope of the present invention.

1. A quick response control design method for an aero-engine starting process, wherein the method can shorten transient state adjusting time on the premise of achieving stable operation of an aero-engine, comprising: firstly, designing an active disturbance rejection controller (ADRC) based on an N-dot control plan; secondly, constructing a competitive particle swarm intelligent control algorithm; and finally, applying the algorithm to a model to obtain a control result, wherein comprising the following steps:
step 1: designing an ADRC based on the N-dot control plan
an ADRC algorithm is adopted instead of a traditional PI control algorithm, and is applied to starting process control of the aero-engine to construct a closed-loop control circuit, and specific steps are as follows:
(1) by controlling the rotor acceleration of the engine, the N-dot control plan ensures that the engine with manufacturing tolerance and performance degradation achieves the goal of consistent transient state performance;
(2) the ADRC mainly comprises the following parts: a tracking differentiator (TD), a linear extended state observer (LESO), and nonlinear state error feedback (NLSEF); and the characteristics are as follows: 1) the contradiction between rapidity and overshoots of a control system is solved by arranging a transient process; 2) an extended state observer is used to estimate disturbance of the system in real time and compensate the disturbance to enhance the robustness of the system; 3) a linear state error combination method is adopted to significantly improve the control function; a second-order tracking differential equation is as follows:
$$\{ \begin{matrix}{v}_{1} ( k + 1 ) = {v}_{1} ( k ) + h * {v}_{2} ( k ) \\ {v}_{2} ( k + 1 ) = {v}_{2} ( k ) h * fhan ( {v}_{1} - {v}_{0} , {v}_{2} , r , {h}_{0} )\end{matrix}$$
where in v₀ is a reference set value of high-pressure shaft rotor acceleration N-dot, and v₁ is a tracking value of reference input; v₂ is a tracking value of an N-dot derivative; r is a velocity factor, which is a physical quantity that determines how fast or slow to track; h is a sampling point of the system; h₀ is a filtering factor; and fhan(v₁−v₀,v₂,r,h₀) is a nonlinear function;
(3) the N-dot control plan and the ADRC controller are combined, which retains the characteristics of the N-dot control plan and introduces the ADRC to enhance strong immunity and strong robustness of closed-loop control;
step 2: constructing a competitive particle swarm intelligent control algorithm used to solve the problem that a traditional optimization algorithm has too many constraints or has multiple extreme values and thus cannot obtain an optimal solution; and specific steps are as follows:
(1) a new competitive particle swarm optimization (CSO) algorithm for large-scale optimization is adopted; the algorithm does not involve neither the individual best position of each particle nor the global best position or the neighborhood best position when updating particles; on the contrary, a paired competitive mechanism is introduced, under which losing particles will update the positions thereof by learning from winning particles;
(2) a minimization problem is:
$$min f = f ( X )$$
$$s . t . X {∈}_{𝒳}$$
wherein χ∈Rⁿ is a set of feasible solutions, and n is the dimension of searching space, i.e., the number of decision variables;
to solve the above optimization problem, a population P(t) containing m particles is randomly initialized and iteratively updated, wherein m is called a population size, and the population size m is assumed to be an even number; and t is a generating index;
each particle has a two-dimensional position, Xₜ(t)=(x_{t,1}(t), x_{t,2}(t), . . . , x_{t,n}(t)), indicating a candidate solution of the above optimization problem, and an n-dimensional velocity vector, Vₜ(t)=(v_{t,1}(t), v_{t,2}(t), . . . , v_{t,n}(t)); in each generation, particles in P(t) are randomly assigned to m/2 pairs and then compete between two particles in each pair; as a result of each competition, particles with better fitness, hereinafter referred to as winners, will be passed directly to the next generation P(t+1) of the population, while losing particles, hereinafter referred to as losers, will update the positions and velocities thereof by learning from the winners; and after learning from the winners, the losers will also be passed to the particle swarm P(t+1), i.e., for the population size of m, an m/2 competition occurs so that all the m particles compete once, and the positions and velocities of m/2 particles will be updated;
X_{w,k}(t) and X_{l,k}(t) as well as V_{w,k}(t) and V_{l,k}(t) are respectively used to indicate positions and velocities of winners and losers in a k^{th} round of a t^{th} generation, wherein k=1, 2, . . . , m/2; therefore, the velocity of the losing particles after the k^{th} competition is updated by using the following learning strategy:
$${V}_{l , k} ( t + 1 ) = {R}_{1} ( k , t ) {V}_{l , k} ( t ) + {R}_{2} ( k , t ) ( {X}_{w . k} ( t ) - {X}_{l . k} ( t ) ) + φ {R}_{3} ( k , t ) ( {X}_{k} ( t ) - {X}_{l , k} ( t ) )$$
meanwhile, the positions of the losers can be updated with new velocities;
$${X}_{l , k} ( t + 1 ) = {X}_{l . k} ( t ) + {V}_{l . k} ( t + 1 )$$
wherein R₁(k,t), R₂(k,t) and R₃(k,t)∈[0,1]ⁿ are three vectors randomly generated after the k^{th} competition and learning process in the t^{th} generation, X̅ₖ(t) is an average position value of correlated particles, and g is a parameter that controls the effect of X̅ₖ(t);
(3) the CSO algorithm is selected to solve the fuel-air ratio optimization problem in the starting process;
step 3: obtaining a control result in combination with the model
(1) optimization result of CSO algorithm: parameters are preset in an optimization program, and then different predicted numbers of steps, different numbers of iterations and different numbers of competing particles are set respectively; and the preset parameters are optimized, an optimized fuel-air ratio curve is input into a starting model, and finally, an optimized high-pressure shaft speed rising curve can be obtained;
(2) optimization result of ADRC based on N-dot control plan: the obtained high-pressure shaft speed curve is taken as a control target value for closed-loop tracking control.

2. (canceled)
